(19) United States
(12) Patent Application Publication
(10) Pub. No.: US 2010/0116207 A1
(43) Pub. Date: May 13, 2010

(54) REACTION CHAMBER

(75) Inventors: Michael Givens, Phoenix, AZ (US); Matthew Goodman, Chandler, AZ (US); Mark Hawkins, Gilbert, AZ (US); Brad Halleck, Salem, OR (US); Herbert Terhorst, (NL)

Correspondence Address: Knobbe, Martens, Olson & Bear LLP, 2040 Main Street, 14th Floor, Irvine, CA, 92614, UNITED STATES, 949-760-0404, 949 760 9502, JCARTEE@KMOB.COM

(73) Assignee: ASM AMERICA, INC., Phoenix, AZ (US)

(21) Appl. No.: 12/613,436

(22) Filed: Nov. 5, 2009

Related U.S. Application Data
(60) Provisional application No. 61/112,604, filed on Nov. 7, 2008.

(51) Int. Cl. C23C 16/00

(52) U.S. Cl. 118/715

(57) ABSTRACT

A reaction chamber having a reaction spaced defined therein, wherein the reaction space is tunable to produce substantially stable and laminar flow of gases through the reaction space. The substantially stable and laminar flow is configured to improve the uniformity of deposition on substrates being processed within the reaction chamber to provide a predictable deposition profile.

### CROSS-REFERENCE TO RELATED APPLICATIONS

The present application claims priority to Provisional Application No. 61/112,604, filed Nov. 7, 2008, the entirety of which is hereby incorporated herein by reference.

### BACKGROUND OF THE INVENTION

1. Field of the Invention

The present invention relates to a semiconductor processing system, and more particularly to a reaction chamber for use in a semiconductor processing system.

2. Description of the Related Art

In the processing of semiconductor devices, such as transistors, diodes, and integrated circuits, a plurality of such devices are typically fabricated simultaneously on a thin slice of semiconductor material such as a substrate, wafer, or workpiece. In one example of a semiconductor processing step during manufacture of such semiconductor devices, the substrate is typically transported into a reaction chamber in which a thin film, or layer, of a material is deposited on an exposed surface of the wafer. Once the desired thickness of the layer of semiconductor material has been deposited onto the surface of the substrate, the substrate is transported out of the reaction chamber for packaging or for further processing.

Known methods of depositing a film of a material onto a surface of a substrate include, but are not limited to: (atmospheric or low-pressure) vapor deposition, sputtering, spray-and-anneal, and atomic layer deposition. Chemical vapor deposition (“CVD”), for example, is the formation of a stable compound on a heated substrate by the thermal reaction or decomposition of certain gaseous compounds within a reaction chamber. The reaction chamber provides a controlled environment for safe deposition of stable compounds onto the substrate.

The type of reaction chamber used for a particular tool or process can vary depending upon the type of process being performed. One type of reaction chamber often used for CVD processes is a horizontal flow, cold-wall reaction chamber in which the reaction chamber includes a generally elongated chamber into which the substrate to be processed is inserted. Process gases are injected or introduced into one end of the reaction chamber and flow along the longitudinal length, across the substrate, and then exit the reaction chamber from the opposing end. When the process gases pass over the heated substrate within the reaction chamber, a reaction occurs at the surface of the substrate which causes a layer of material to be deposited onto the substrate.

As the gases flow along the length of a horizontal flow reaction chamber, the flow pattern may becomes uneven or localized areas of turbulence can be formed as a result of the gases contacting various structures within the reaction chamber, such as the susceptor, substrate, or the walls of the reaction chamber itself. When these localized areas of turbulence overlap with the surface of the substrate being processed, the uniformity of deposition across the surface of the substrate worsens. The localized areas of turbulence of the process gases that react with the substrate may cause bumps, ridges, or other localized deposition formations that reduce the uniformity of deposition. The profile of the surface of the substrate after deposition can be unpredictable due in part to the non-laminar and unstable flow of gases through the reaction chamber.

A need therefore exists for an improved reaction chamber that is tunable to reduce or eliminate the uneven or localized areas of turbulence of the flow of process gases through the reaction chamber to improve the uniformity of deposition, or produce a predictable deposition profile, on a substrate being processed.

### SUMMARY OF THE INVENTION

In one aspect of the present invention, a reaction chamber is provided. The reaction includes an upper chamber having a stationary upper wall and a first inlet in fluid communication with the upper chamber. The first inlet is configured to allow at least one gas to be introducible into the upper chamber. The reaction chamber also includes a lower chamber having a lower wall. The lower chamber is in fluid communication with the upper chamber. The reaction chamber further includes a plate separating at least a portion of the upper chamber and at least a portion of the lower chamber. The plate is spaced apart from the upper wall by a first distance, and the plate is spaced apart from the lower wall by a second distance. An outlet is disposed opposite the first inlet. The upper chamber is tunable for producing a substantially stable and laminar flow of gases between the first inlet and the outlet by adjusting the first distance.

In another aspect of the present invention, a method for optimizing deposition uniformity on a substrate in a reactor of a semiconductor processing tool is provided. The method includes providing a split-flow reaction chamber. The split-flow reaction chamber comprises an upper chamber and a lower chamber, wherein the upper and lower chambers are at least partially separated by a plate, and gases are introducible into both the upper and lower chambers. The method further includes providing a susceptor located within the split-flow reaction chamber, wherein the susceptor is disposed between the upper and lower chambers. The susceptor is configured to support at least one substrate. The method further includes tuning dimensions of the split-flow chamber for producing substantially stable and laminar flow of gases within the upper chamber.

In still another aspect of the present invention, a reaction chamber is provided. The reaction chamber includes an upper wall, a lower wall, and a pair of opposing side walls connecting the upper and lower walls to define a reaction space therewithin. An inlet is located at one end of the reaction space, and an outlet is located at an opposing end of the reaction space. A velocity of at least one gas flowing through the reaction space is tunable by adjusting the upper wall relative to the lower wall to produce substantially stable and laminar flow of the at least one gas through the reaction space.

In yet another aspect of the present invention, a reaction chamber is provided. The reaction chamber includes a reaction space in which a substrate is supportable, and the reaction space has a volume. The reaction chamber also includes an inlet through which at least one gas is introducible into the reaction space, and an outlet through which gases within the reaction space exit the reaction space. The volume is tunable to provide substantially stable and laminar flow of gases through the reaction space.

In a further aspect of the present invention, a reaction chamber is provided. The reaction chamber includes a volume defined by a first wall, a second wall, opposing side walls, an inlet located at one end of the first and second walls, and an outlet located at an opposing end of the first and second walls. Gases are flowable through the volume at a first flow velocity. The first wall is adjustable to change the volume and such a change in the volume causes a corresponding increase or decrease in the first velocity resulting in a second velocity of the gases flowing through the volume. The second velocity of the gases flowing through the volume provides substantially laminar gas flow between the inlet and the outlet.

In another aspect of the present invention, a reaction chamber is provided. The reaction chamber includes a reaction space defined by a width, length, and height. The reaction chamber also includes a controller configured to produce a gas flow velocity of gases flowable through the reaction space. At least one of the width, length, and height is adjustable to produce substantially stable and laminar flow of said gases through the reaction space.

In another aspect of the present invention, a reaction chamber comprises an upper wall, a lower wall, a pair of opposing side walls connecting said upper and lower walls to define a reaction space therewithin, an inlet located at one end of said reaction space, and an outlet located at an opposing end of said reaction space. The upper wall is spaced from the lower wall by a first distance, the opposing side walls are spaced apart by a second distance, and the inlet and outlet are spaced apart by a third distance. At least one of the first, second, and third distances is selected by using modeling software to produce substantially stable and laminar flow of at least one gas through said reaction space.

Advantages of the present invention will become more apparent to those skilled in the art from the following description of the embodiments of the invention which have been shown and described by way of illustration. As will be realized, the invention is capable of other and different embodiments, and its details are capable of modification in various respects. Accordingly, the drawing(s) and description are to be regarded as illustrative in nature and not as restrictive.

### BRIEF DESCRIPTION OF THE DRAWINGS

FIG. 1 is an isometric view of a semiconductor processing system.

FIG. 2 is a side cross-sectional view of a portion of the semiconductor processing system of FIG. 1.

FIG. 3 is a top view of a portion of the semiconductor processing system of FIG. 2.

FIG. 4 is a bottom isometric view of an embodiment of a reaction chamber.

FIG. 5 is a top isometric view of the reaction chamber of FIG. 4.

FIG. 6 is a side cross-sectional view of the reaction chamber, taken along line 6-6′ of FIG. 3.

FIG. 7 is a side cross-sectional view of another embodiment of a semiconductor processing system.

### DETAILED DESCRIPTION OF THE PREFERRED EMBODIMENT

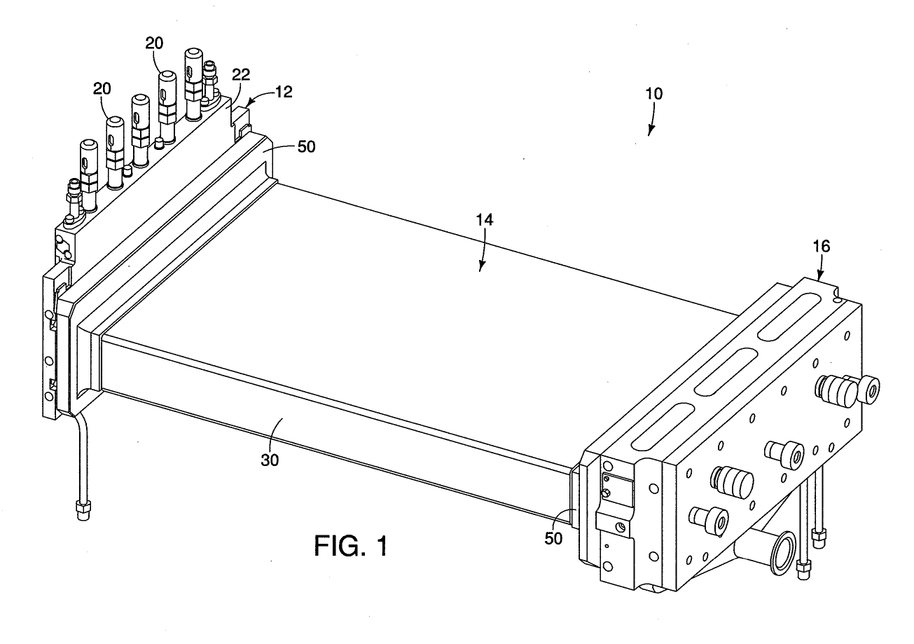

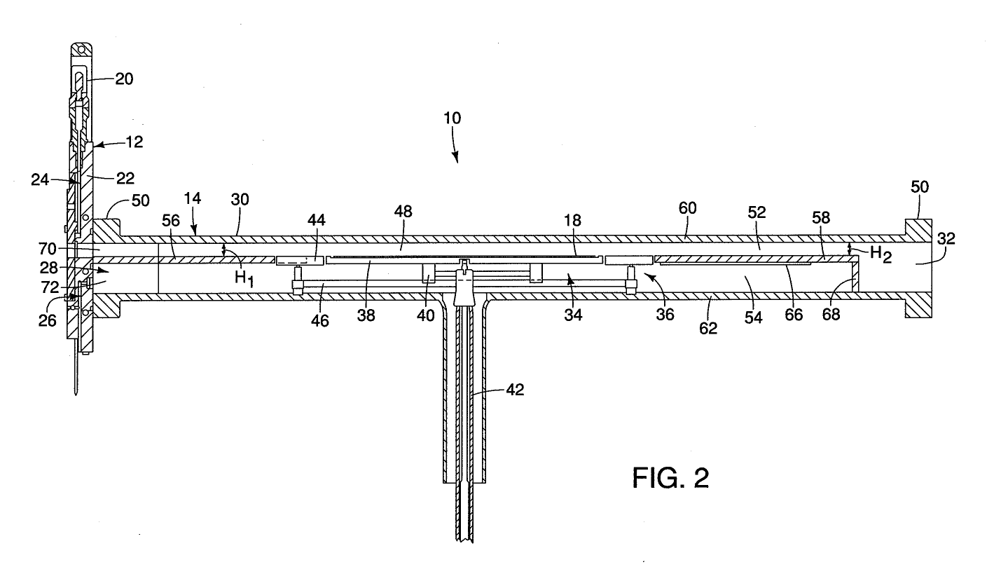

Referring to FIG. 1, an exemplary embodiment of a semiconductor processing system 10 is shown. The semiconductor processing system 10 includes an injector assembly 12, a reaction chamber assembly 14, and an exhaust assembly 16. The semiconductor processing system 10 is configured to receive a substrate 18 (FIG. 2) to be processed within the reaction chamber assembly 14. The injector assembly 12 is configured to introduce various gases into the reaction chamber assembly 14, wherein at least one chemical reaction takes place within the reaction chamber assembly 14 between the gases introduced therein and the substrate 18 being supported therein. The unreacted process gases as well as the exhaust gases are then removed from the reaction chamber assembly 14 through the exhaust assembly 16.

As shown in FIGS. 1-2, an embodiment of the injector assembly 12 includes a plurality of injectors 20 operatively connected to an inlet manifold 22. In an embodiment, the inlet manifold 22 includes a first gas line 24 and a second gas line 26. The first gas line 24 is configured to transfer gases from the injectors 20, through the inlet manifold 22, and to the upper portion of the reaction chamber 30 of the reaction chamber assembly 14. The second gas line 26 is operatively connected to a gas source and is configured to transfer gases from the gas source, through the inlet manifold 22, and to the lower portion of the reaction chamber 30 of the reaction chamber assembly 14. It should be understood by one skilled in the art that the inlet manifold 22 may include any number of gas lines for carrying gases to be introduced into the reaction chamber 30. In an embodiment, the exhaust assembly 16 is removably connected to the outlet 32 of the reaction chamber 30 of the reaction chamber assembly 14.

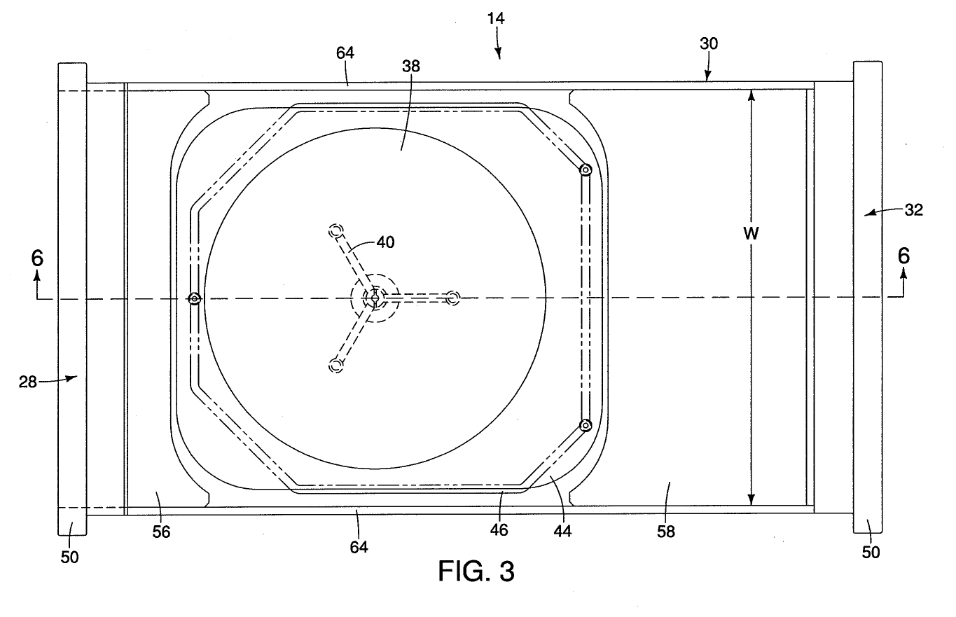

In an embodiment, the reaction chamber assembly 14 includes a reaction chamber 30, a substrate support assembly 34, and a susceptor ring assembly 36, as shown in FIGS. 2-3. The substrate support assembly 34 includes a susceptor 38, a susceptor support member 40 operatively connected to the susceptor 38, and a tube 42 operatively connected to the susceptor support member 40 and extending therefrom. During operation, a substrate 18 is supported on the susceptor 38. The substrate support assembly 34 is rotatable for rotating the substrate 18 during operation if such rotation is desired for the deposition process.

In an embodiment, the susceptor ring assembly 36 includes a susceptor ring 44 and a susceptor ring support 46, as illustrated in FIGS. 2-3. The susceptor ring 44 is configured to surround the susceptor 38 to eliminate or reduce the amount of heat loss from the outer radial edge of the susceptor 38 during processing. The susceptor ring support 46 extends from the lower surface of the reaction chamber 30 and is operatively connected to the susceptor ring 44 to maintain the susceptor ring in a substantially fixed location relative to the substrate support assembly 34.

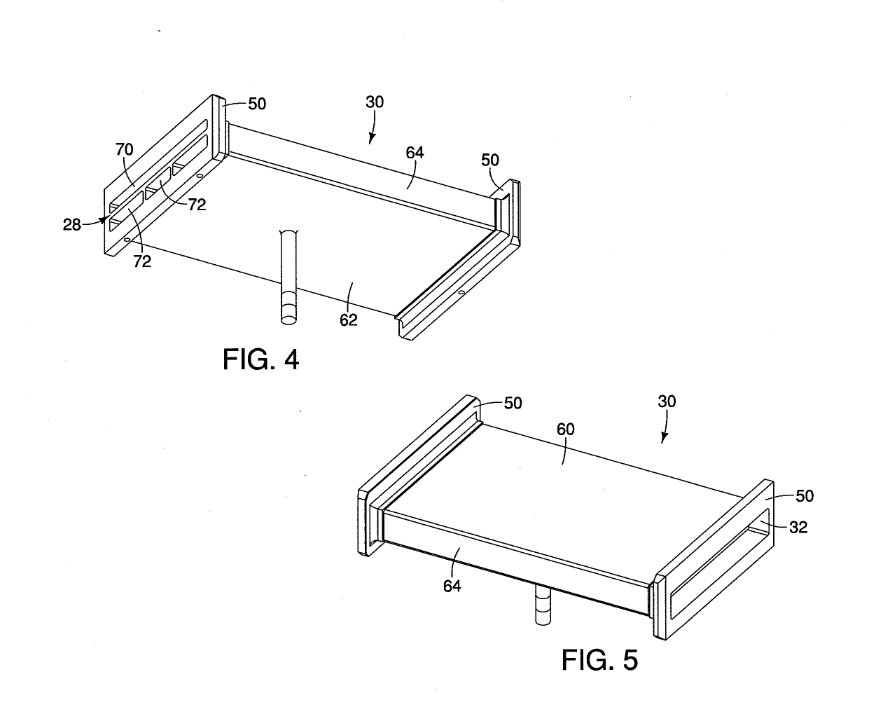

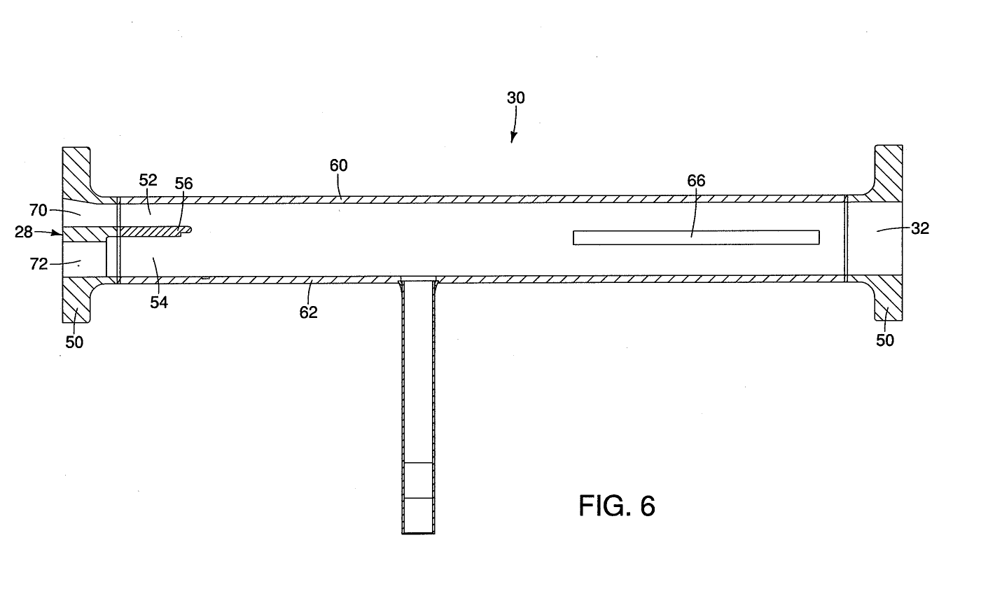

Referring to FIGS. 2-6, an exemplary embodiment of a reaction chamber 30 is shown. The illustrated reaction chamber 30 is a horizontal flow, single-pass, split flow, cold wall chamber. Although the illustrated reaction chamber 30 is illustrated as a split flow chamber, it should be understood by one skilled in the art that the improved reaction chamber 30 can be a split flow chamber or a single chamber. In an embodiment, the reaction chamber 30 is formed of quartz. The reaction chamber 30 illustrated in FIGS. 1-2 is typically used for processes in which the pressure within the reaction chamber 30 is at or near atmospheric pressure. It should be understood by one skilled in the art that the concepts discussed below are in relation to the atmospheric reaction chamber 30 illustrated, but the same concepts can be incorporated into a reduced pressure reaction chamber in which the pressure within the reaction chamber is less than atmospheric pressure. The reaction chamber 30 includes an inlet 28, an outlet 32, and a reaction space 48 located between the inlet 28 and the outlet 32. Both the inlet 28 and outlet 32 are surrounded by a flange 50. The injector assembly 12 (FIG. 1) is operatively connected to the flange 50 surrounding the inlet 28, and the exhaust assembly 16 (FIG. 1) is operatively connected to the flange 50 surrounding the outlet 32. The reaction chamber 30 includes an upper chamber 52 and a lower chamber 54, wherein the upper chamber 52 is separated from the lower chamber 54 by a first plate 56 adjacent to the inlet 28 and by a second plate 58 adjacent to the outlet 32. The first plate 56 is spaced apart from the second plate 58 longitudinally to allow room for the substrate support assembly 34 and the susceptor ring assembly 36 to be located therebetween. As illustrated in FIG. 2, the first plate 56, second plate 58, substrate support assembly 34, and the susceptor ring assembly 36 define the demarcation between the upper and lower chambers 52, 54. In an embodiment, the upper chamber 52 is in fluid communication with the lower chamber 54. In another embodiment, the upper chamber 52 is substantially sealed from the lower chamber 54.

In an embodiment, the reaction chamber 30 includes an upper wall 60, a lower wall 62, and opposing side walls 64 extending between the upper and lower walls 60, 62, as illustrated in FIGS. 2-6. In an embodiment, the upper and lower walls 60, 62 are substantially parallel relative to each other. In another embodiment, the upper and lower walls 60, 62 are not parallel to each other. For example, in an embodiment, the upper wall 60 (not shown) is curved upwardly between the opposing side walls 64 such that the upper wall 60 has a semi-circular shape. In another embodiment, the upper wall 60 is angled upwardly from the opposing side walls 64 to form a longitudinal junction that is substantially parallel to the longitudinal axis of the reaction chamber 30. It should be understood by one skilled in the art that the upper and/or lower walls 60, 62 of the reaction chamber 30 can be formed as planar or non-planar walls. It should also be understood by one skilled in the art that the upper wall 60 and the lower wall 62 may be formed having the same or a different shape. The upper wall 60, lower wall 62, and the side walls 64 extend between the opposing flanges 50 to form a volume within the reaction chamber 30. The reaction space 48 is at least a portion of the total volume within the reaction chamber 30, and process gases react with the substrate 18 disposed within the reaction space 48 to form a layer of deposition on the substrate 18.

In an embodiment of a split flow reaction chamber 30, as illustrated in FIGS. 2-6, the reaction space 48 is the volume generally defined by the upper wall 60, first plate 56, second plate 58, substrate support assembly 34, susceptor ring assembly 36, side walls 64, the inlet 28, and the outlet 32. The reaction space 48 is generally the volume defined within the upper chamber 52 of the split flow reaction chamber 30. It should be understood by one skilled in the art that in an embodiment of a single-chamber reaction chamber 30 (not shown), the reaction space 48 is defined by the upper and lower walls 60, 62, side walls 64, inlet 28, and the outlet 32. The reaction space 48 of a single chamber reaction chamber 30 can be defined as the entire volume of the reaction chamber 30. The reaction space 48 can also be defined as the volume immediately adjacent to the upper, exposed surface of the substrate 18 being processed. The reaction space 48 provides a volume in which the chemical reaction between the substrate 18 (FIG. 2) and the process gases introduced into the reaction chamber 30 occurs.

In an embodiment, the first plate 56 is integrally formed with the side walls 64 of the reaction chamber 30, as shown in FIGS. 2-6. In another embodiment, the first plate 56 is formed separately from the reaction chamber 30 and is inserted into the reaction chamber 30 during assembly thereof. When formed separately, the first plate 56 can be disposed, for example, on a pair of ledges (not shown) that are integrally formed with the side walls 64 of the reaction chamber 30. In an embodiment, the first plate 56 is oriented in a substantially horizontal manner, or substantially parallel to the upper and lower walls 60, 62 of the reaction chamber 30. In another embodiment, the first plate 56 is oriented at an angle relative to the upper and lower walls 60, 62. In an embodiment, a lead edge of the first plate 56 is substantially aligned with the front surface of the flange 50 surrounding the inlet 28. In another embodiment, the lead edge of the first plate 56 is spaced inwardly from the front surface of the flange 50 surrounding the inlet 28. The first plate 56 provides a barrier between the upper and lower chambers 52, 54 adjacent to the inlet 28 of the reaction chamber 30.

In an embodiment, the first plate 56 divides the inlet 28 to provide separate and distinct inlets into the upper and lower chambers 52, 54 of the reaction chamber 30, as illustrated in FIGS. 2-4 and 6. In an embodiment, the inlet 28 can include an upper inlet 70 in fluid communication with the upper chamber 52 for introducing gases therein, and a lower inlet 72 in fluid communication with the lower chamber 54 for introducing gases therein. In an embodiment, the upper inlet 70 and/or the lower inlet 72 can be divided into multiple spaced-apart inlets, wherein each spaced-apart inlet introduces gases into the same chamber of the split flow reaction chamber 30. In an embodiment, the lead edge of the first plate 56 is substantially aligned with the front surface of the flange 50 adjacent to the inlet 28 such that the first plate 56 contacts the inlet manifold 22 (FIG. 2), thereby separating the gases from the first gas line 24 from the gases from the second gas line 26.

In an embodiment, the second plate 58 is integrally formed with the side walls 64 of the reaction chamber 30. In another embodiment, the second plate 58 is formed separately from the reaction chamber 30, as illustrated in FIGS. 2-3 and 6, and is inserted into the reaction chamber 30 during assembly thereof. When formed separately, the second plate 58 can be disposed, for example, on a pair of opposing ledges 66 that are integrally formed with the side walls 64 of the reaction chamber 30. In an embodiment, the second plate 58 is oriented in a substantially horizontal manner, or substantially parallel to the upper and lower walls 60, 62 of the reaction chamber 30. In another embodiment, the second plate 58 is oriented at an angle relative to the upper and lower walls 60, 62. In an embodiment, the second plate 58 extends from a position immediately adjacent to the trailing edge of the susceptor ring 44. In an embodiment, a trailing edge of the second plate 58 is substantially aligned with the rear surface of the flange 50 surrounding the outlet 32. In another embodiment, the trailing edge of the second plate 58 is spaced inwardly from the rear surface of the flange 50 surrounding the outlet 32. The second plate 58 provides a barrier between the upper and lower chambers 52, 54 adjacent to the outlet 32 of the reaction chamber 30.

In an embodiment, the edge of the second plate 58 directed toward the outlet 32 is spaced inwardly from the outlet 32 such that the outlet 32 includes a single aperture through which all of the gases introduced into the reaction chamber 30 from both the first gas line 24 and the second gas line 26 exit the reaction chamber 30, as illustrated in FIGS. 2 and 5. In another embodiment, the rearwardly-directed surface of the second plate 58 is substantially coplanar with the flange 50 surrounding the outlet 32 such that the second plate 58 provides an upper outlet (not shown) and a lower outlet (not shown), wherein the gases introduced into the upper chamber 52 exit the reaction chamber 30 through the upper outlet and at least a portion of the gases introduced into the lower chamber 54 exit the reaction chamber 30 through the lower outlet.

In an embodiment, the second plate 58 includes a blocking plate 68 that extends downwardly therefrom, as shown in FIG. 2. The blocking plate 68 extends to a position adjacent to, or in contact with, the lower wall 62 of the reaction chamber 30. In an embodiment, the blocking plate 68 extends substantially the entire distance between the opposing side walls 64. In another embodiment, the blocking plate 68 extends only a portion of the width between the opposing side walls 64. The blocking plate 68 is configured to block at least a portion of the gas flow within the lower chamber 54 between the inlet 28 and outlet 32. In operation, the blocking plate 68 is further configured to create a pressure differential between the lower chamber 54 and the upper chamber 52 such that the pressure within the lower chamber 54 is greater than the pressure in the upper chamber 52, thereby forcing at least a portion of the gases introduced into the lower chamber 54 to enter the upper chamber 52. For example, gases within the lower chamber 54 can flow to the upper chamber 52 by flowing through gaps between the susceptor ring assembly 36 and the plates 56, 58, or through a gap between the susceptor ring assembly 36 and the substrate support assembly 34. By forcing at least a potion of the gases introduced into the lower chamber 54 to flow into the upper chamber 52, the flow of gases into the upper chamber 52 reduces or eliminates potential flow of process gases from the upper chamber 52 into the lower chamber 54.

The injectors 20 are configured to introduce at least one gas into the upper chamber 52 of a split flow reaction chamber 30. The injectors 20 introduce the gases via the inlet 28 to produce a flow velocity of gases within the reaction space 48 between the inlet 28 and outlet 32 along a substantially horizontal flow path. In general, a computer-operated controller can be provided for controlling the gas flow from various sources, as well the injectors 20. The injectors 20 are tunable, or adjustable, to produce different flow velocities within the reaction space 48. The injectors 20 can be individually adjusted in order to modify or adjust the flow profile of gases exiting the injectors into the reaction chamber 30. For example, the velocity of gases exiting each injector 20 may be the same or different so as to produce an overall flow profile of gases being introduced into the reaction chamber 30 from the inlet manifold 22 that has substantially stable and laminar flow between the inlet 28 and the outlet 32. In an embodiment, the injectors 20 are adjustable to introduce gases into the upper chamber 52 of a reaction chamber 30 to produce a flow velocity of the gases between 5-100 cm/s for processes performed at substantially atmospheric pressure within the reaction chamber 30, and more particularly between about 15-40 cm/s. In another embodiment, the injectors 20 are adjustable to produce a flow velocity of the gases between 20-25 cm/s for processes performed at substantially atmospheric pressure within the reaction chamber 30. It should be understood by one skilled in the art that the flow velocity of gases through the reaction chamber 30 may be different for processes performed at reduced pressures, or pressures less than atmospheric pressure.

The improved reaction chamber 30 is configured to stabilize the gas flow, or to reduce and/or eliminate localized areas of turbulence of process gases between the inlet 28 and the outlet 32, thereby increasing the uniformity of deposition on substrates 18 being processed within the reaction chamber 30. The improved reaction chamber 30 is also configured to optimize the flow of gases through the reaction space 48 to improve the laminar flow of gases. This stabilized and laminar flow of gases between the inlet 28 and the outlet 32 results in a more uniform deposition across the surface of the substrate 18. It should be understood by one skilled in the art that a more uniform deposition on substrates being processed will provide a deposition profile that, while not necessarily completely planar, will at least be a more predictable profile with a stable and laminar flow of gases across the surface of the substrate being processed. The improved reaction chamber 30 can be used to process any size substrates 18 including, but not limited to, 150 mm substrates, 200 mm substrates, 300 mm substrates, and 450 mm substrates. The dimensions of the reaction chamber 30 discussed below are directed to a reaction chamber 30 for processing 300 mm substrates, but it should be understood by one skilled in the art that the optimization techniques used to improve the laminar flow and uniform deposition within the reaction chamber for processing 300 mm substrates can likewise be used to improve the laminar flow of gases and the uniform deposition on the substrates in reaction chambers 30 configured to process other sizes of substrates.

In an exemplary embodiment of a split flow reaction chamber 30 for processing 300 mm substrates 18, the reaction space 48 is at least a portion of the volume encompassed within the upper chamber 52, as shown in FIG. 2-3. The opposing side walls 64 provide a width W therebetween, and the upper wall 60 provides a first height H₁ between the upper wall 60 and the first plate 56 and a second height H₂ between the upper wall 60 and the second plate 58. In an embodiment, the first height H₁ between the upper wall 60 and the first plate 56 is the same as the second height H₂ between the upper wall 60 and the second plate 58. In another embodiment, the first height H₁ between the upper wall 60 and the first plate 56 is different than the second height H₂ between the upper wall 60 and the second plate 58. The width W between the opposing side walls 64 is wide enough to allow a susceptor 38 and susceptor ring 44 to be located therebetween. In an embodiment, the reaction space 48 has a substantially rectangular cross-section along the length of the reaction chamber 30 defined by the width W and the length between the flanges 50, as illustrated in FIG. 2. Although the length and width of the reaction chamber 30 can be modifiable, it should be understood by one skilled in the art that these dimensions of the reaction chamber 30 would likely remain substantially constant between each reaction chamber 30 due to dimensional constraints of the tool into which the reaction chamber 30 would be installed.

In an embodiment, the upper wall 60 is integrally formed with the side walls 64 to define a portion of the upper chamber 52. When the upper wall 60 is integrally formed with the side walls 64, the upper chamber 52 is tunable to produce substantially stable and laminar flow of gases between the inlet 28 and outlet 32 within the upper chamber 52. In an embodiment, the upper chamber 52 is tunable using a modeling program to model the gas flow within the upper chamber 52 to optimize the flow of gases through the upper chamber. In optimizing the flow of gases through the upper chamber 52 of the reaction chamber 30, the first and second heights H₁, H₂, the width W, the length of the reaction space 48, and/or the velocity of gases flowing between the inlet 28 and outlet 32 within the upper chamber 52 are modifiable. The modeling program can be used to pre-determine the dimensions of the upper chamber 52 to optimize the flow of gases therethrough. The modeling can also be used to pre-determine the gas velocity and flow profile of the gases introduced into the reaction chamber by the gas injectors 20.

In an embodiment for tuning the upper chamber 52, the dimensions of the upper chamber 52 are fixed and the velocity and flow profile from the injectors 20 is modeled to optimize the flow velocity from each injector 20 and the flow profile of gases exiting the inlet manifold 22 to provide substantially stable and laminar gas flow between the inlet 28 and the outlet 32. In another embodiment for tuning the upper chamber 52, the flow velocity from each injector 20 and the flow profile of gases exiting the inlet manifold 22 are fixed and the dimensions of the upper chamber 52 are modeled to optimize the dimensions to provide substantially stable and laminar gas flow between the inlet 28 and the outlet 32.

In yet another embodiment for tuning the upper chamber 52, the first and second heights H₁, H₂ are modifiable while also modifying the flow velocity and profile of gases being introduced into the upper chamber 52. The upper wall 60 of the reaction chamber 30 is modeled by adjusting the upper wall 60 to increase or decrease the first and second heights H₁, H₂. As the height of the upper wall 60 is adjusted relative to the first and second plates 56, 58, the velocity of the gases exiting the injectors are also adjusted to maintain a pre-determined flow profile or to optimize the flow profile of gases exiting the inlet manifold 22. For example, for a pre-determined flow velocity of process gases of about 20-25 cm/s through the upper chamber 52 that produces a substantially stable and laminar flow, as the upper wall 60 is modeled at a greater distance away from the first and second plates 56, 58, the injectors 20 are adjusted to introduce more gases into the upper chamber 52 to maintain the pre-determined flow velocity of gases therethrough. The upper chamber 52 is tunable by comparing the flow pattern of the gases therethrough to optimize the first and second heights H₁, H₂ to produce substantially stable and laminar flow at the pre-determined flow velocity. It should be understood by one skilled in the art that the dimensions of the upper chamber, the velocity of gases from the injectors 20, the flow profile of gases exiting the inlet manifold 22, or any combination thereof can be modified and modeled (e.g., using modeling software) to optimize the gas flow within the upper chamber 52 to provide a substantially stable and laminar flow of gases across the surface of the substrate being processed to produce a substantially uniform layer of material deposited on the substrate.

In one embodiment, the dimensions of the upper chamber 52 (or of the entire reaction chamber 30) are fixed during operation, and adjustment of the upper wall 60 is determined prior to operation by using modeling software to pre-determine dimensions of the reaction space 48. In one embodiment, the upper wall 60 is moveable during processing, such as by using a ceiling insert 80 (described below) in conjunction with an automated position control system.

In embodiments employing a cross-flow reaction chamber 30 such as the reaction chamber illustrated in FIG. 2, in which the substrate 18 is transferred into the reaction chamber 30 from the upper inlet 70 on the front, optimizing the volume of the upper chamber 52 of the reaction chamber 30 can be accomplished by adjusting the relative distance between the upper wall 60 and the first and second plates 56, 58. It should be understood by one skilled in the art that the first height H₁ should not be reduced such that the substrate 18 cannot be carried into the upper chamber 52 and disposed on the susceptor 38. The first height H₁ should be at least large enough to allow an end effector (not shown) to be inserted and removed through the upper inlet 70. However, for reaction chambers (not shown) in which the susceptor 38 is lowered such that the substrate 18 is disposed on the susceptor 38 at a position substantially below the first and second plates 56, 58, the first and second heights H₁, H₂ can be reduced until the first and second plates 56, 58 almost touch the upper wall 60 but still maintain a small gap between therebetween to allow process gases to flow through the upper chamber 52.

In an embodiment, the upper chamber 52 is tunable by maintaining the upper wall 60 at a pre-determined location in which the first and second heights H₁, H₂ remain fixed values and the injectors 20 are adjusted to modify the flow velocity and/or the flow profile introduced into the upper chamber 52. The injectors 20 are adjusted to increase or decrease the flow velocity of gases through the inlet manifold 22 and into the upper chamber 52 and the resulting flow pattern through the reaction chamber is modeled.

In yet another embodiment, the upper chamber 52 is tunable by modeling the flow pattern of gases therethrough by adjusting the location of the upper wall 60 relative to the first and second plates 56, 58 to modify the first and second heights H₁, H₂ as well as adjusting the injectors 20, wherein the volume of the upper chamber 52 as well as the flow velocity and flow profile of gas introduced into the upper chamber 52 are optimized to produce a substantially stable and laminar flow of gases through the upper chamber 52.

In an exemplary process of tuning the upper chamber 52 of a split flow reaction chamber 30 for processing 300 mm substrates, the upper wall 60 is spaced above the first and second plates 56, 58 to provide a first and second height H₁, H₂ of about 1.2 inches (3.05 cm) and a width W between the opposing side walls 64 of about 17 inches (43.18 cm), wherein the volume of the upper chamber 52 is about 590 in³ (9.67 liters). The fluid dynamic modeling, using a flow velocity of gases about 20-25 cm/s and the exemplary dimensions above, indicates a substantially stable and laminar flow is produced through the upper chamber 52, thereby optimizing the uniformity of deposition on substrates processed within the reaction chamber 30. In another exemplary process of tuning the upper chamber 52 of a split flow reaction chamber 30 for processing 300 mm substrates, the upper wall 60 is spaced above the first and second plates 56, 58 to provide a first and second height H₁, H₂ of about 0.8 inches (2.03 cm) and a width between the opposing side walls 64 of about 17 inches (43.18 cm), wherein the volume of the upper chamber 52 is about 393 in³ (6.44 liters). The fluid dynamic modeling, using a flow velocity of gases about 20-25 cm/s and the exemplary dimensions above, indicates a substantially stable and laminar flow is produced through the upper chamber 52, thereby optimizing the uniformity of deposition on substrates processed within the reaction chamber 30. It should be understood by one skilled in the art that any number of combinations of the first and second heights H₁, H₂ and the flow velocity and flow profile introduced into the upper chamber 52 can be used to produce a substantially stable and laminar flow of gases through the upper chamber 52 to provide an optimized uniformity of deposition on the substrates being produced within the reaction chamber 30.

Once the modeling of the upper chamber 52 to optimize the flow of gases therethrough to produce a substantially stable and laminar flow to produce more uniform deposition on substrates is completed, the reaction chamber 30 can be built to the dimensions determined during the modeling process. After the reaction chamber 30 is installed in a semiconductor processing system 10, the injectors 20 are calibrated to the settings determined during the modeling process to produce the determined flow velocity and profile. It should be understood by one skilled in the art that further fine adjustments of the injectors 20 may be required to fully optimize the flow of gases through the upper chamber 52 to produce a more uniform deposition on substrates 18 being processed within the reaction chamber 30.

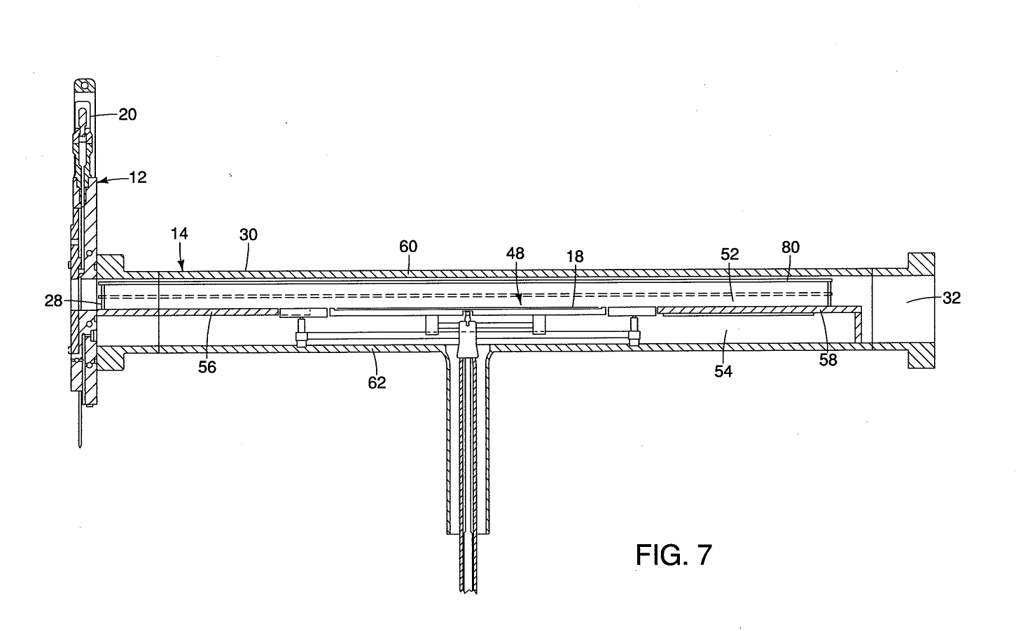

In another embodiment, a ceiling insert 80 is inserted into the upper chamber 52 of the reaction chamber 30, as illustrated in FIG. 7. The ceiling insert 80 provides an adjustable upper boundary to the reaction space 48 within the upper chamber 52. The ceiling insert 80 is translatable relative to the first and second plates 56, 58. In an embodiment, the ceiling insert 80 is manually adjustable to vary the heights H₁ and H₂. In another embodiment, the ceiling insert 80 is mechanically adjustable by a mechanical adjuster (not shown) such that the ceiling insert 80 can be adjusted between cycles of processing substrates or during a substrate processing cycle. Persons of skill in the art will readily appreciate that there are a variety of different mechanical and/or electromechanical structures and means for adjusting the position of the ceiling insert 80 to vary the heights H₁ and H₂, and that any of such structures and means can be employed, giving due consideration to any size and access constraints that may apply. The ceiling insert 80 is adjustable to increase or decrease the effective volume of the upper chamber 52 by preventing process gases from the injectors 20 to flow between the ceiling insert 80 and the upper wall 60 of the reaction chamber 30. The upper chamber 52 is tunable by adjusting the relative position of the ceiling insert 80 to optimize the flow pattern of gases through the reaction space 48 to produce a substantially linear flow pattern between the inlet 28 and outlet 32. The ceiling insert 80 allows the upper chamber 52 to be easily tunable for different processes or process recipes without requiring a completely new reaction chamber 30 to be produced and installed. The ceiling insert 80 can also be adjustable to control the front-to-back and/or side-to-side slope such that the ceiling insert 80 is not substantially parallel to the upper wall 60 or the first and second plates 56, 58. The ability to adjust the ceiling insert 80 in this manner may aide in controlling or eliminating process depletion or other asymmetric effects within the upper chamber 52.

In an embodiment, tuning the upper chamber 52 by using a ceiling insert 80 to optimize the uniformity of deposition on a substrate 18 includes processing a substrate 18 within the reaction chamber 30 to determine the uniformity of deposition on the substrate 18 when the ceiling insert 80 is at a first height H₁. The ceiling insert 80 is then adjusted to a second height H₂, and another substrate 18 is processed to determine a second uniformity of deposition on the substrate 18. Further processing of substrates 18 may be performed to further optimize the flow velocity and flow profile of gas introduced into the reaction space 48 to produce a more uniform deposition on the substrates 18 being processed in the reaction chamber 30. It should be understood by one skilled in the art that once the size and/or shape of the fully optimized upper chamber 52 is determined, the ceiling insert 80 may be fixed (i.e., non-moveable) within the reaction chamber 30 or the ceiling insert 80 may remain adjustable for further optimization of different processes or recipes within the reaction chamber 30. It should also be understood by one skilled in the art that once the location of the ceiling insert 80 is determined to fully optimized upper chamber 52, a reaction chamber 30 having an upper chamber 52 in which the upper wall 60 of the reaction chamber 30 is located at the position of the ceiling insert 80 in the fully optimized location can be produced and installed in semiconductor processing systems 10.

While preferred embodiments of the present invention have been described, it should be understood that the present invention is not so limited and modifications may be made without departing from the present invention. The scope of the present invention is defined by the appended claims, and all devices, process, and methods that come within the meaning of the claims, either literally or by equivalence, are intended to be embraced therein.

What is claimed is:

1. A reaction chamber comprising:
an upper chamber having a stationary upper wall;
a first inlet in fluid communication with said upper chamber, said first inlet configured to allow at least one gas to be introducible into said upper chamber;
a lower chamber having a lower wall, said lower chamber being in fluid communication with said upper chamber;
a plate separating at least a portion of said upper chamber and at least a portion of said lower chamber, said plate being spaced apart from said upper wall by a first distance and said plate being spaced apart from said lower wall by a second distance; and
an outlet disposed opposite said first inlet;
wherein said upper chamber is tunable for producing substantially stable and laminar flow of gas between said first inlet and said outlet by optimizing said first distance.

2. The reaction chamber of claim 1, wherein a ceiling insert is disposable between said plate and said upper wall, said ceiling insert is adjustable for optimizing said first distance.

3. The reaction chamber of claim 2, wherein said ceiling insert is adjustable by manual adjustment.

4. The reaction chamber of claim 2, wherein said ceiling insert is mechanically adjustable.

5. The reaction chamber of claim 1, wherein a modeling program is used to tune said upper chamber by pre-determining said first distance.

6. The reaction chamber of claim 1, wherein the reaction chamber is configured so that at least a portion of a gas introducible into said lower chamber flows into said upper chamber.

7. (canceled)

8. (canceled)

9. (canceled)

10. A reaction chamber comprising:
an upper wall, a lower wall, and a pair of opposing side walls connecting said upper and lower walls to define a reaction space therewithin;
an inlet located at one end of said reaction space;
an outlet located at an opposing end of said reaction space; and
wherein a velocity of at least one gas flowing through said reaction space is tunable by adjusting said upper wall relative to said lower wall to produce substantially stable and laminar flow of said at least one gas through said reaction space.

11. The reaction chamber of claim 10, wherein said upper wall, said lower wall, and said opposing side walls are fixed relative to each other during operation, and adjustment of said upper wall relative to said lower wall is determined prior to operation using modeling software to pre-determine dimensions of said reaction space.

12. The reaction chamber of claim 10, wherein said upper wall is movable during processing to allow said upper wall to be adjustable relative to said lower wall to produce substantially stable and laminar flow of said at least one gas through said reaction space.

13. A reaction chamber comprising:
a reaction space in which a substrate is supportable, said reaction space having a volume;
an inlet through which at least one gas is introducible into said reaction space;
an outlet through which gases within said reaction space exit said reaction space; and
wherein said volume is tunable to provide substantially stable and laminar flow of gases through said reaction space.

14. A reaction chamber comprising a volume defined by a first wall, a second wall, opposing side walls, an inlet located at one end of said first and second walls, and an outlet located at an opposing end of said first and second walls, wherein gases are flowable through said volume at a first flow velocity and a first flow profile, and wherein said first wall is adjustable to change said volume and such change in said volume causes a corresponding increase or decrease in said first velocity and first flow profile resulting in a second velocity and a second flow profile of said gases flowing through said volume, and said second velocity and said second flow profile of said gases flowing through said volume provides substantially stable and laminar gas flow between said inlet and said outlet.

15. The reaction chamber of claim 14, wherein said first wall, said second wall, and said opposing side walls are fixed relative to each other during operation and modeling software is used to adjust said first wall prior to operation.

16. The reaction chamber of claim 14, wherein said first wall is movable during processing to allow said volume to be changed.

17. The reaction chamber of claim 14, wherein said second velocity is about 5-100 cm/s.

18. The reaction chamber of claim 14, wherein said second velocity is about 20-25 cm/s.

19. A reaction chamber comprising:
a reaction space defined by a width, length, and height;
a controller configured to produce a gas flow velocity of gases flowable through said reaction space; and
wherein at least one of said width, length, height, and gas flow velocity is adjustable to produce substantially stable and laminar flow of said gases through said reaction space.

20. The reaction chamber of claim 19, wherein said gas flow velocity is increasable or decreasable to provide substantially stable and laminar flow of said gases through said reaction space.

21. The reaction chamber of claim 19, wherein said height is about 2.16 cm, said length is about 63 cm, and said width is about 27.8 cm.

22. The reaction chamber of claim 21, wherein said gas flow velocity of said gases is between about 10 and 18 cm/s.

23. The reaction chamber of claim 21, wherein said gas flow velocity of said gases is about 14 cm/s.

24. The reaction chamber of claim 19, wherein said height is about 1.2 inches, said length is about 29.87 inches, said width is about 17 inches, and said gas flow velocity is about 22.5 cm/s through said reaction space.

25. The reaction chamber of claim 19, wherein said gas flow velocity of said gases is between about 15 and 40 cm/s.

26. The reaction chamber of claim 19, wherein said gas flow velocity of said gases is about 22.5 cm/s.

27. (canceled)

28. A reaction chamber comprising:
an upper wall;
a lower wall, the upper wall being spaced from the lower wall by a first distance;
a pair of opposing side walls connecting said upper and lower walls to define a reaction space therewithin, the opposing side walls being spaced apart by a second distance;
an inlet located at one end of said reaction space; and
an outlet located at an opposing end of said reaction space, the inlet and outlet being spaced apart by a third distance;
wherein at least one of the first, second, and third distances is selected by using modeling software to produce substantially stable and laminar flow of at least one gas through said reaction space.
